(19) United States
(12) Patent Application Publication
(10) Pub. No.: US 2023/0051246 A1
(43) Pub. Date: Feb. 16, 2023

(54) INFORMATION PROCESSING DEVICE, INFORMATION PROCESSING METHOD, COMPUTER PROGRAM PRODUCT, AND INFORMATION PROCESSING SYSTEM

(71) Applicant: KABUSHIKI KAISHA TOSHIBA, Tokyo (JP)

(72) Inventor: Makoto SATO, Shinagawa Tokyo (JP)

(73) Assignee: KABUSHIKI KAISHA TOSHIBA, Tokyo (JP)

(21) Appl. No.: 17/680,228

(22) Filed: Feb. 24, 2022

(30) Foreign Application Priority Data
Aug. 11, 2021 (JP) 2021-131448

(51) Int. Cl. G05B 19/418; G06F 30/20

(52) U.S. Cl. CPC G05B 19/41885; G05B 19/4183; G06F 30/20

(57) ABSTRACT

An information processing device includes one or more processors. The one or more processors are configured to: perform, by using a physical model for performing a simulation of operations of a plurality of electronic devices, the simulation, and output a plurality of pieces of first data representing outputs by the plurality of electronic devices; and estimate, based on the first data and a plurality of pieces of second data representing outputs obtained by operating the plurality of electronic devices, mapping data representing a correspondence between the plurality of electronic devices that output the first data and the plurality of electronic devices that output the second data.

### CROSS-REFERENCE TO RELATED APPLICATIONS

This application is based upon and claims the benefit of priority from Japanese Patent Application No. 2021-131448, filed on Aug. 11, 2021; the entire contents of which are incorporated herein by reference.

### FIELD

Embodiments described herein relate generally to an information processing device, an information processing method, a computer program product, and an information processing system.

### BACKGROUND

A facility management system (FMS) for managing equipment by information technology (IT) has been introduced into various pieces of equipment. The FMS includes a controller that controls a large number of sensors and devices. An FMS application has been introduced for grasping the situation of the entire equipment by the sensors to perform optimal control or the like. The FMS application is implemented by a configuration including an FMS engine, a front end (FE), FMS data, a sensor database (DB), FMS metadata, and the like. Herein, the FMS metadata is information for the FMS to know what physical quantity the signal point of the sensor corresponds to.

There is a case where it is necessary to estimate data (e.g., metadata or mapping data) representing the correspondence between such sensors and physical quantities. For example, techniques have been proposed for generating metadata by analyzing sensor time-series data by using a text mining method.

However, in the conventional techniques, there have been cases where data representing a correspondence between a sensor and a physical quantity cannot be estimated with high accuracy. For example, in the conventional techniques, when there is a plurality of sensors of the same type, there have been cases where a difference between the sensors cannot be analyzed.

### BRIEF DESCRIPTION OF THE DRAWINGS

FIG. 1 is a block diagram illustrating an information processing device according to an embodiment;

FIG. 2 is a diagram illustrating an example of a data structure of metadata;

FIG. 3 is a diagram illustrating an example of a data structure of sensor data;

FIG. 4 is a diagram illustrating an example of an equipment layout diagram included in a physical model;

FIG. 5 is a diagram illustrating an example of a data structure of an information model;

FIG. 6 is a diagram illustrating an example of a data structure of mapping data;

FIG. 7 is a flowchart illustrating a mapping estimation process according to the embodiment;

FIG. 8 is a diagram illustrating an example of correlation data;

FIG. 9 is a diagram illustrating an example of a matching degree of a character string for each concept;

FIG. 10 is a diagram illustrating an example of a calculated matching degree;

FIG. 11 is a diagram illustrating an example of a calculation result of a matching degree of waveforms;

FIG. 12 is a diagram illustrating an example of an added matching degree;

FIG. 13 is a diagram illustrating an example of a confirmation screen;

FIG. 14 is a diagram illustrating an example of correlation data;

FIG. 15 is a diagram illustrating an example of calculation of a correlation error for each combination;

FIG. 16 is a diagram illustrating an example of mapping data;

FIG. 17 is a diagram illustrating a configuration example of an information processing system;

FIG. 18 is a diagram illustrating a configuration example of the information processing system; and

FIG. 19 is a hardware configuration diagram illustrating the information processing device according to the embodiment.

### DETAILED DESCRIPTION

According to an embodiment, an information processing device includes one or more processors. The one or more processors are configured to: perform, by using a physical model for performing a simulation of operations of a plurality of electronic devices, the simulation, and output a plurality of pieces of first data representing outputs by the plurality of electronic devices; and estimate, based on the first data and a plurality of pieces of second data representing outputs obtained by operating the plurality of electronic devices, mapping data representing a correspondence between the plurality of electronic devices that output the first data and the plurality of electronic devices that output the second data.

Preferred embodiments of an information processing device according to the present invention will be described in detail below with reference to the accompanying drawings. In the following, a description will be mainly given of an example applied to a system (e.g., FMS) that estimates a correspondence between a sensor and a physical quantity by using, for example, sensor data (an example of an output by an electronic device) detected by a plurality of sensors (an example of electronic devices). The applicable system is not limited to the above system. The same method can be applied to any system including a plurality of electronic devices that outputs output data. For example, the present embodiment may be applied to a system that monitors an abnormality of a control signal (an example of an output by an electronic device) of a controller (an example of an electronic device) that controls a sensor.

When a more advanced artificial intelligence (AI) application is added to the FMS, two options are generally available, that is, the FMS is upgraded or an independent system such as an intelligent facility manager (IFM) is retrofitted to the outside. The latter can be expected to be introduced at a lower cost. On the other hand, the IFM needs to generate a control signal after obtaining sensor data of the device by borrowing the function of the FMS via the FMS connector, and control the device by borrowing the function of the FMS. In such a case, the IFM requires metadata (mapping data) for knowing what physical quantity a required signal point corresponds to.

The signal point represents a point at which a signal to be managed is outputted. For example, in the case of an FMS, a sensor may correspond to a signal point. If the FMS manages control signals of the controller, the control signals of the controller may correspond to signal points.

The metadata estimation apparatus supports estimation of metadata of the FMS, or estimation of metadata of the IFM using sensor time-series data. The estimation of metadata can also be interpreted as estimating the correspondence between a plurality of sensors to which metadata created in advance by, for example, an external system is given and a plurality of sensors that is actually installed. Therefore, the metadata estimation apparatus is also referred to as a sensor mapping apparatus.

The information processing device of the present embodiment can function as a metadata estimation apparatus. The information processing device of the present embodiment performs a physical simulation based on a physical model, and estimates metadata by using sensor time-series data that is a result of the physical simulation and sensor time-series data detected by a sensor.

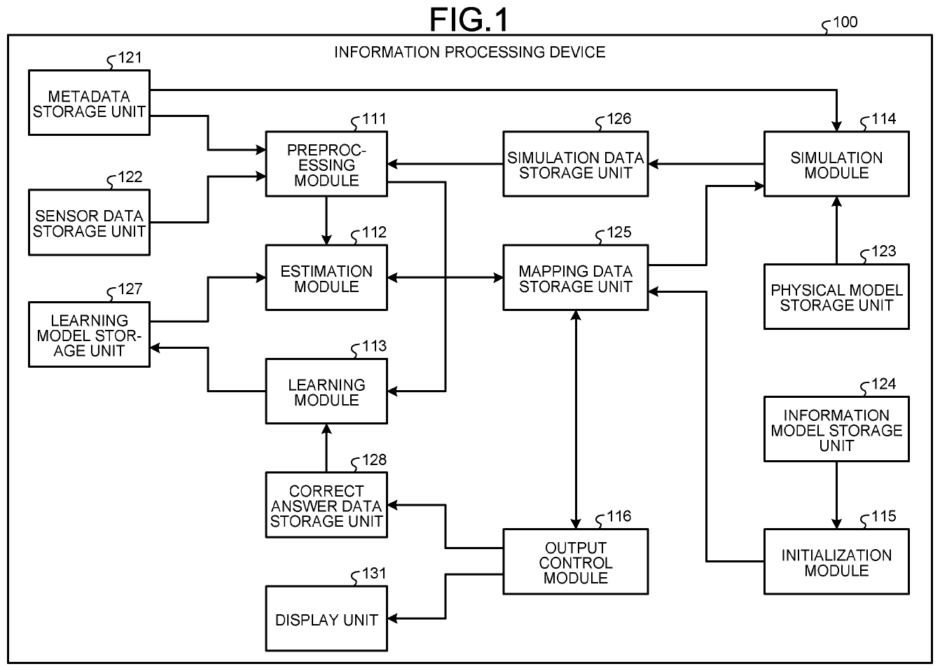

FIG. 1 is a block diagram illustrating an example of a configuration of an information processing device 100 according to the present embodiment. As illustrated in FIG. 1, the information processing device 100 includes a metadata storage unit 121, a sensor data storage unit 122, a physical model storage unit 123, an information model storage unit 124, a mapping data storage unit 125, a simulation data storage unit 126, a learning model storage unit 127, a correct answer data storage unit 128, a display unit 131, a preprocessing module 111, an estimation module 112, a learning module 113, a simulation module 114, an initialization module 115, and an output control module 116.

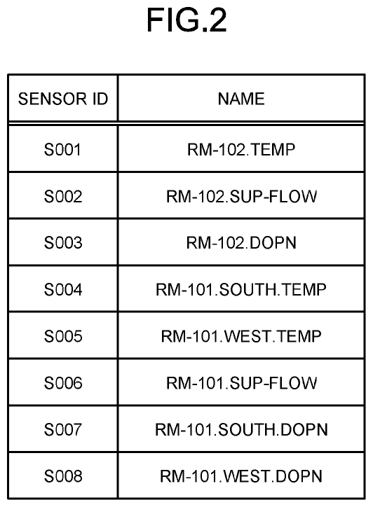

The metadata storage unit 121 stores metadata created in advance. FIG. 2 is a diagram illustrating an example of a data structure of metadata stored in the metadata storage unit 121. The metadata includes a sensor ID and a name. The sensor ID is identification information for identifying a sensor (signal point). The example of FIG. 2 describes eight types of sensor IDs S001 to S008. The name is a name of the sensor identified by the sensor ID.

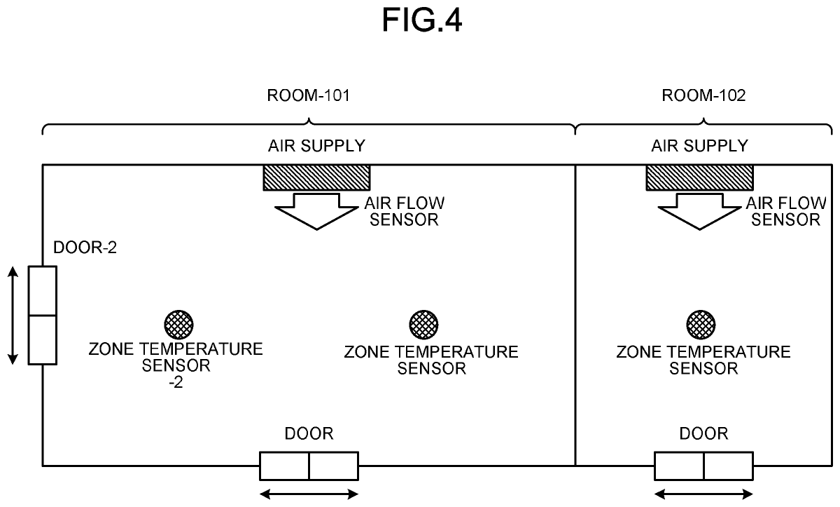

The sensors identified by the eight types of sensor IDs correspond to sensors included in a physical model illustrated in FIG. 4 to be discussed below. On the other hand, the name may be given by a vendor (such as a vendor that has constructed an existing FMS) different from a user (such as an engineer that constructs an IFM) that currently performs estimation of metadata. Therefore, the user may not be able to completely distinguish the type of the sensor from only the name. In order to solve such a problem, a metadata estimation apparatus is used which estimates data representing a correspondence between a sensor and a physical quantity.

Estimating the correspondence between a sensor and a physical quantity can also be interpreted as estimating what physical quantity the sensor detects or estimating the type of the sensor.

The items included in the metadata are not limited to the example illustrated in FIG. 2. For example, the metadata may further include other items such as remarks and units (e.g., ° C.). If the metadata has not been created in advance, the metadata storage unit 121 may not be provided.

The sensor data storage unit 122 stores sensor data detected by a sensor. The sensor data may be in any format, but may be in a format associated with the detected time, for example. The sensor data may be in the format of time-series data representing temporal changes in values. In the following, sensor data in such a format may be referred to as sensor time-series data.

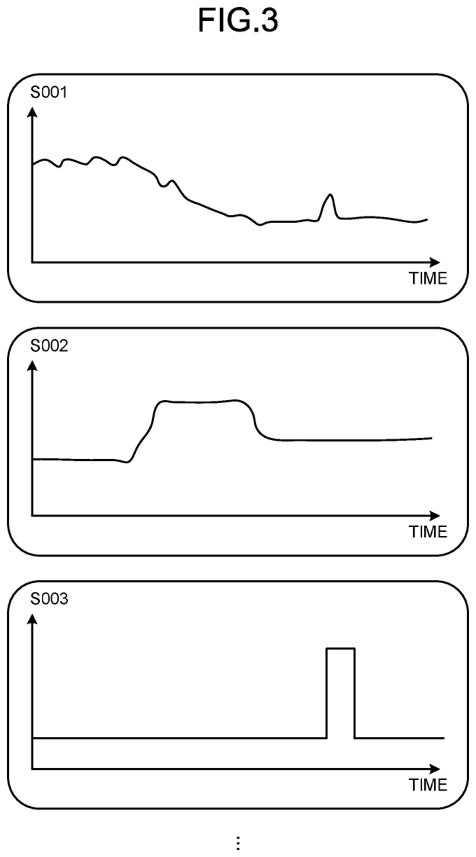

FIG. 3 is a diagram illustrating an example of a data structure of sensor data stored in the sensor data storage unit 122. FIG. 3 illustrates an example of sensor data represented in the format of time-series data. As illustrated in FIG. 3, the sensor data is stored in association with the sensor ID.

The physical model storage unit 123 stores a physical model used when the simulation module 114 performs simulation. The physical model is, for example, a model representing positions, structures, and operating conditions of elements such as an area (e.g., a building or a room) in which equipment to be managed is installed, equipment (e.g., a door or an air conditioner), and a sensor.

FIG. 4 is a diagram illustrating an example of an equipment layout diagram included in the physical model. The equipment layout diagram illustrates the spatial positional relationship of equipment. The example of FIG. 4 illustrates an equipment layout diagram including the following elements:
Two locations “Room-101” and “Room-102”
An air outlet (Air Supply) of an air conditioner, doors (Door and Door-2), and temperature sensors (Zone Temperature Sensor and Zone Temperature Sensor-2), which are disposed in each location
A sensor (Air Flow Sensor) that detects a flow of air from the air outlet

As described above, the physical model may include information other than the equipment layout diagram. For example, information indicating the thermal insulation performance of the wall of each room may be included in the physical model.

The information model storage unit 124 stores an information model representing a hierarchical relationship of equipment. The information model may be prepared in advance, for example, for generating metadata by the text mining method described above. The information model storage unit 124 may store an information model prepared in advance in this manner. Information corresponding to the information model may be included in the physical model. In this case, the information model storage unit 124 may not be provided.

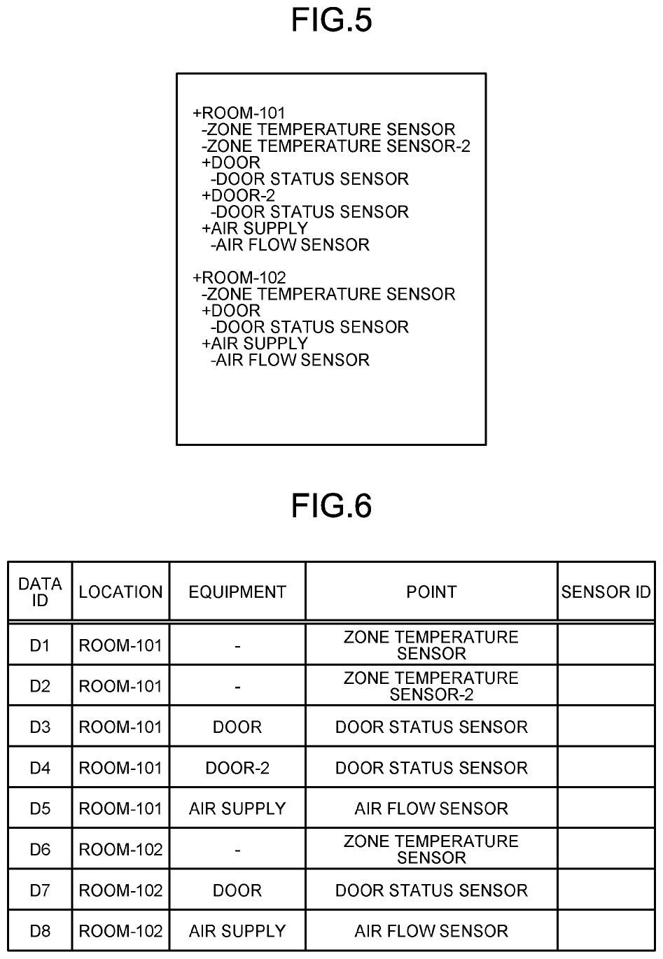

FIG. 5 is a diagram illustrating an example of the data structure of the information model stored in the information model storage unit 124. FIG. 5 is an example of an information model representing a hierarchical relationship among each pieces of equipment included in the equipment layout diagram illustrated in FIG. 4. For example, FIG. 5 illustrates that five types of sensors are included in “Room-101”, and three types of sensors are included in “Room-102”.

The physical model and the information model may be prepared independently of the metadata stored in the metadata storage unit 121. Therefore, even if the same sensor is indicated, the “name” of the metadata may not match the name of the sensor in the information model. Mapping data representing these correspondences is then estimated.

The mapping data storage unit 125 stores mapping data to be estimated. In the present embodiment, mapping data represents a correspondence between a sensor (sensor ID) that has detected sensor data to which metadata (second metadata, e.g., FIG. 2) created in advance has been given and a sensor that has detected sensor data to which metadata (first metadata) based on, for example, a physical model (e.g., the physical model in FIG. 4) has been given.

FIG. 6 is a diagram illustrating an example of the data structure of the mapping data stored in the mapping data storage unit 125. As illustrated in FIG. 6, the mapping data includes a data ID, a location, equipment, a point, and a sensor ID.

The data ID is identification information for identifying which sensor has detected the sensor data. Therefore, the data ID can be interpreted as identification information of the sensor that has detected the sensor data.

The location represents a location (area) where the sensor is installed. In the examples of FIGS. 4 and 5, the location corresponds to rooms (Room-101 and Room-102). The equipment represents equipment other than sensors in the location. In the examples of FIGS. 4 and 5, the equipment corresponds to the air outlet (Air Supply) of the air conditioner, and the doors (Door and Door-2). The point represents a sensor (signal point). Although FIG. 6 illustrates an example in which the sensor is specified by information of three hierarchical layers of location, equipment, and point, the method of specifying the sensor is not limited thereto. For example, the sensor may be specified by one piece of information obtained by integrating these three pieces of information.

The simulation data storage unit 126 stores simulation results (simulation data) obtained by the simulation module 114. The simulation data may be in any format as long as the simulation data includes at least information used by the estimation module 112 in the estimation process. The information used in the estimation process is, for example, sensor time-series data obtained by simulating a temporal change of sensor data.

The learning model storage unit 127 stores a learning model used by the estimation module 112 in the estimation process. The learning model is a model having a function of improving performance by machine learning using correct answer data. For example, the learning model is a model learned so as to input the sensor data and the simulation data and output the matching degree therebetween.

The learning model may be a model in any format. For example, the learning model include a neural network model, a support vector machine (SVM), and a model used in Case-based reasoning. When the matching degree between character strings is obtained, a model in a table format in which a plurality of character strings and the matching degree are associated with each other may be used as the learning model.

The correct answer data storage unit 128 stores correct answer data that can be used for machine learning of the learning model. The correct answer data is created based on, for example, correction designated by the user with respect to the estimated mapping data.

The storage units can be configured by any generally used storage medium such as a flash memory, a memory card, a random access memory (RAM), a hard disk drive (HDD), and an optical disk.

The storage units may be a physically different storage medium, or may be implemented as a different storage area of the physically same storage medium. Further, each of the storage units may be implemented by a plurality of physically different storage media.

The display unit 131 is an example of an output device that outputs various types of information processed by the information processing device 100. The display unit 131 is, for example, a display device such as a display that displays information.

The preprocessing module 111 performs preprocessing for converting various pieces of data into a format used in the estimation process performed by the estimation module 112. For example, the preprocessing module 111 performs preprocessing such as text mining, time-series waveform analysis, and time-series correlation analysis on the sensor data and the simulation data.

The preprocessing can include a process of extracting feature data representing features of various pieces of data. For example, the preprocessing module 111 extracts feature data (an example of first feature data) representing a feature of simulation data (an example of first data). The preprocessing module 111 extracts feature data (an example of second feature data) representing a feature of sensor data (an example of second data).

In a case where the estimation process performed by the estimation module 112 includes a process of estimating correspondence based on the matching degree between character strings, the preprocessing may include a process of extracting character strings as feature data by analyzing (text mining) metadata, for example.

The estimation module 112 performs an estimation process of estimating mapping data. For example, the estimation module 112 estimates mapping data by using sensor data detected by a plurality of sensors and simulation data. Details of the estimation process will be discussed below. In a case where the preprocessing is performed on the sensor data and the simulation data, the estimation module 112 estimates the mapping data by using each data (e.g., feature data) after the preprocessing.

The learning module 113 learns a learning model used by the estimation module 112 in the estimation process. For example, the learning module 113 learns a learning model by using correct answer data of mapping data set by the user or other persons with reference to the mapping data estimated by the estimation module 112.

The simulation module 114 performs simulation using a physical model. For example, the simulation module 114 performs simulation and outputs, as simulation data, a plurality of sensor time-series data representing outputs by the plurality of sensors. The simulation module 114 may perform the simulation by any method. For example, the simulation module 114 may perform the simulation using a simulation execution web service, for example.

The initialization module 115 initializes mapping data. The initialized mapping data is, for example, mapping data in which the sensor ID column is not set. FIG. 6 corresponds to a diagram illustrating the initialized mapping data.

The output control module 116 controls output of various types of information by the information processing device 100. For example, the output control module 116 outputs a screen including the estimated mapping data to the display unit 131.

Each of the above units (the preprocessing module 111, the estimation module 112, the learning module 113, the simulation module 114, the initialization module 115, and the output control module 116) is implemented by, for example, one or more processors. For example, each of the above units may be implemented by causing a processor such as a central processing unit (CPU) to execute a program, that is, by software. Each of the above units may be implemented by a processor such as a dedicated integrated circuit (IC), that is, hardware. Each of the above units may be implemented by using software and hardware in combination. When a plurality of processors is used, each processor may implement one of the units or may implement two or more of the units.

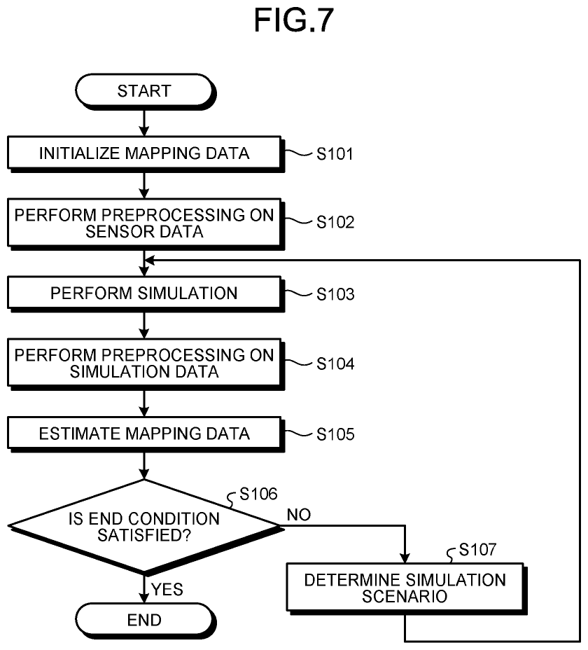

A mapping estimation process performed by the information processing device 100 according to the present embodiment configured as described above will then be described. FIG. 7 is a flowchart illustrating an example of the mapping estimation process in the present embodiment.

The initialization module 115 first initializes mapping data (step S101). For example, the initialization module 115 generates mapping data as illustrated in FIG. 6 with reference to the information model of the information model storage unit 124, and stores the mapping data in the mapping data storage unit 125.

The preprocessing module 111 reads the sensor data stored in the sensor data storage unit 122 and performs preprocessing on the read sensor data (step S102). As described above, the preprocessing is a process such as text mining, time-series waveform analysis, and time-series correlation analysis.

The simulation module 114 performs simulation using the physical model stored in the physical model storage unit 123, and stores simulation data in the simulation data storage unit 126 (step S103).

The preprocessing module 111 reads the simulation data stored in the simulation data storage unit 126, and performs preprocessing on the read simulation data (step S104). As will be discussed below, step S103 and step S104 related to simulation may be skipped.

The estimation module 112 estimates the mapping data by using the learning model stored in the learning model storage unit 127 and the result of the preprocessing, and stores the estimation result in the mapping data storage unit 125 (step S105).

The estimation module 112 determines whether or not the estimation of the mapping data is ended, that is, whether or not an end condition of the mapping estimation process is satisfied (step S106). The end condition is, for example, that an index such as the number of repetitions of a loop and the number or ratio of data IDs of which each is not determined to have one corresponding sensor ID reaches a specified value.

If the end condition is not satisfied (step S106: No), the simulation module 114 may determine a condition of a simulation to be performed next (hereinafter referred to as a simulation scenario) based on the estimated mapping data (mapping data obtained in advance) (step S107).

For example, the simulation module 114 may determine a simulation scenario such that simulation is performed only in equipment corresponding to a data ID for which a sensor ID of mapping data is not determined. The simulation scenario can reduce simulation time and improve accuracy. The simulation module 114 may determine a simulation scenario based on sensor data obtained in advance. For example, in a case where the sensor data includes only data of a specific period (e.g., August), the simulation module 114 may determine the simulation scenario such that the climate of the specific period is assumed. The determination of such a simulation scenario allows the simulation time to be shorten.

For example, when the mapping data is immediately after initialization (e.g., FIG. 6), the sensor IDs are not determined for all the data IDs. Therefore, the simulation module 114 may skip the simulation (step S103). In this case, the preprocessing of the simulation data (step S104) is also skipped.

After the simulation scenario is determined, the process returns to step S103, and the simulation module 114 performs simulation according to the determined simulation scenario.

If it is determined in step S106 that the end condition is satisfied (step S106: Yes), the mapping estimation process ends.

The estimated mapping data may be outputted to the display unit 131 or other display units by the output control module 116. For example, the estimated mapping data may be able to be confirmed by the user, and the simulation scenario may further be determined in step S107 in accordance with the designation of determination or the designation of change by the user. The details of such processing will be discussed below.

The mapping estimation process will be further described in detail below.

In step S101, the initialization module 115 initializes the mapping data, and stores the mapping data as illustrated in FIG. 6. In the example of FIG. 6, there are eight types of data (sensors) to be estimated which correspond to the data IDs: D1 to D8. An object of the mapping estimation process is to map the sensor IDs of correct sensors (signal points) to the respective data IDs, in other words, to appropriately determine the correspondence relationship between the data IDs: D1 to D8 and the sensor IDs: S001 to S008.

In step S102, the preprocessing module 111 performs preprocessing on the sensor data. For the sensor time-series data as illustrated in FIG. 3, the preprocessing module 111 performs, as preprocessing, time-series feature extraction processing for extracting one or more feature amounts among, for example, an average value, a maximum value, a minimum value, a variation amount, and a Fourier transform coefficient. In other words, in the preprocessing, one or more quantitative values representing the features of the time-series waveform are determined. The preprocessing module 111 may extract, by time-series correlation analysis, a correlation in which when sensor data of a certain sensor changes, sensor data of another specific sensor is likely to change. The time-series correlation analysis may be performed by any method. For example, a method can be applied which extracts a certain amount change as a change event and performs event correlation analysis.

In the example of FIG. 4, there are the two temperature sensors “Zone Temperature Sensor” and “Zone Temperature Sensor-2”, of which the latter is installed closer to the “Door-2”. Therefore, it is expected that the correlation between the change in the sensor data of the “Door Status Sensor” for detecting that the “Door-2” opens and the change in the sensor data of the “Zone Temperature Sensor-2” will increase. In the present embodiment, the use of the result of such correlation analysis allows, even if two temperature sensors are of the same type, the two temperature sensors to be distinguished from each other.

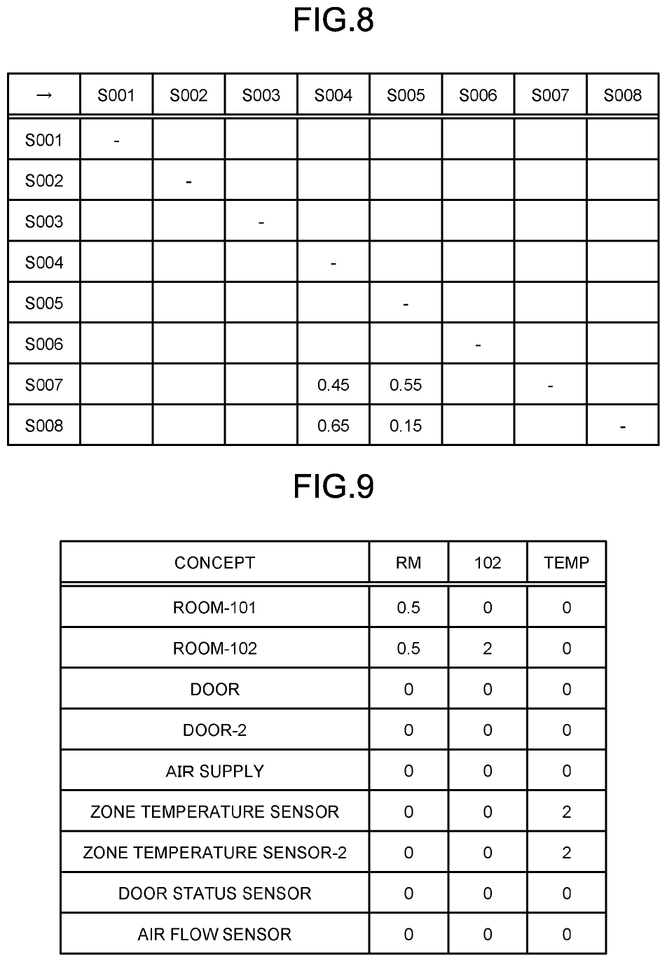

FIG. 8 is a diagram illustrating an example of correlation data representing a correlation analysis result. The correlation data is represented by, for example, a value indicating the strength of correlation between the sensor IDs corresponding to the sensor data. In the example of FIG. 8, a smaller value means that the correlation is stronger. A correlation analysis may be performed in which a larger value indicates a stronger correlation. FIG. 8 illustrates that there is a strong correlation between the sensor data having the sensor ID of S008 and the sensor data having the sensor ID of S005.

If metadata has been obtained, preprocessing may be performed on the metadata. The preprocessing module 111 performs preprocessing such as character string separation processing on the metadata, for example. For example, the preprocessing module 111 separates the character string “RM-102.TEMP”, which is the name corresponding to the sensor ID: S001 of the metadata illustrated in FIG. 2, into three character strings “RM”, “102”, and “TEMP”, and outputs a character string list {RM, 102, TEMP} including these character strings.

In steps S103 and S104, simulation using the physical model and preprocessing on the simulation data are performed. As described above, these processes may be skipped. Depending on the skip of the simulation, the estimation process performed by the estimation module 112 may have the following pattern.

Pattern 1: When simulation is skipped, mapping data is estimated using sensor data or metadata without using simulation data.

Pattern 2: When simulation is performed, mapping data is estimated by using simulation data (simulation data on which preprocessing has been performed) and sensor data (sensor data on which preprocessing has been performed).

For example, in a case where the metadata as illustrated in FIG. 2 has been created in advance, the first processes of step S103 and step S104 may be skipped, and the mapping data may be estimated using the metadata according to the pattern 1. The mapping data may be further estimated by performing simulation according to the pattern 2 on the data for which the correspondence cannot be estimated. In a case where the metadata as illustrated in FIG. 2 has not been created in advance, the first processes of step S103 and step S104 may not be skipped, and the mapping data may be estimated according to the pattern 2.

An example of the estimation process (step S105) performed by the estimation module 112 in the case of the pattern 1 will be described. The following example is an example of estimating using a learning model in a table format in which a plurality of character strings and matching degrees are associated with each other.

The estimation module 112 obtains, by using such a learning model, the matching degree between each element (may also be hereinafter referred to as concept) included in the information model and each character string in the character string list obtained by the preprocessing on the metadata. FIG. 9 is a diagram illustrating an example of a matching degree of a character string for each concept included in the information model of FIG. 5. As illustrated in FIG. 9, the information model of FIG. 5 includes nine concepts. FIG. 9 illustrates an example of the matching degrees with each of three character strings “RM”, “102”, and “TEMP” included in the character string list {RM, 102, TEMP} obtained by preprocessing the name corresponding to the sensor ID: S001.

In this example, a larger value of the matching degree indicates a larger degree of matching. The matching degree represents the likelihood of occurrence of a case where the character string “RM” is given to a concept “Room-101”, for example. The matching degree can be interpreted as indicating a similarity degree (a level of similarity).

The estimation module 112 can determine the matching degree related to the character string between the sensor corresponding to each data ID and the sensor specified by the metadata created in advance, from the calculation result of the matching degree between such a concept and the character string included in the character string list.

For example, the name “RM-102.TEMP” corresponding to the sensor ID: S001 has a matching degree of 2.5 (=0.5+2.0) with respect to the concept “Room-102” and has a matching degree of 2 with respect to the concept “Zone Temperature Sensor”. On the other hand, as illustrated in FIG. 6, the data ID: D6 is specified by character strings “Room-102” and “Zone Temperature Sensor”. Therefore, the matching degree between the sensor ID: S001 and the data ID: D6 is 4.5 (=2.5+2).

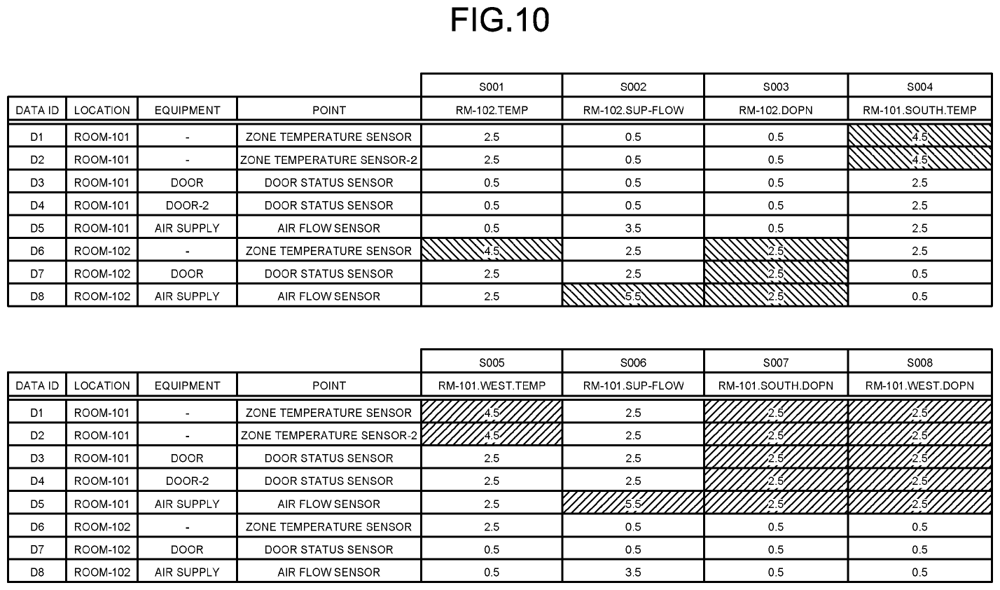

FIG. 10 is a diagram illustrating an example of the matching degree calculated for all combinations of eight data IDs: D1 to D8 and eight sensor IDs: S001 to S008.

The estimation module 112 may calculate the matching degree of waveforms of the sensor time-series data instead of or together with the matching degree of the character strings as described above. An example of a method of calculating the matching degree of the sensor time-series data will be described below.

For example, a plurality of pieces of collation data is stored in advance, in a storage unit such as the learning model storage unit 127, which is a result obtained by performing preprocessing (e.g., feature extraction processing) on sensor time-series data detected by each of a plurality of sensors of known types. The estimation module 112 can calculate the matching degree of waveforms of the sensor time-series data for each type of sensor by collating each of the plurality of pieces of collation data with the data obtained by the preprocessing in step S102.

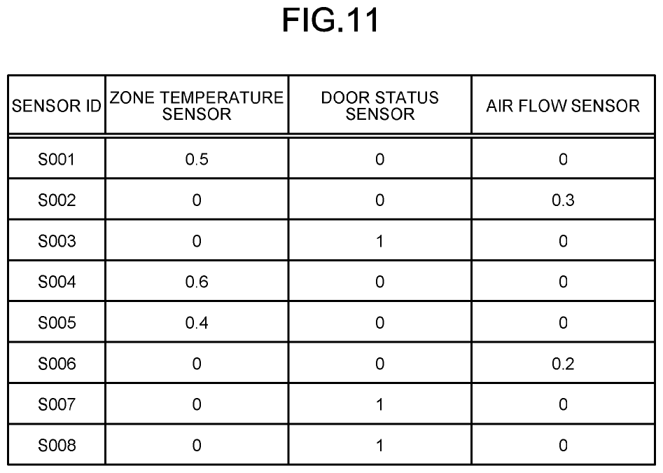

FIG. 11 is a diagram illustrating an example of a calculation result of the matching degree of waveforms. FIG. 11 illustrates an example of the matching degree of waveforms with the collation data of the following three types of sensors for each of the sensor time-series data corresponding to the sensor IDs: S001 to S008. A larger value of the matching degree of the waveforms indicates a larger degree of matching.
Zone Temperature Sensor
Door Status Sensor
Air Flow Sensor

For example, FIG. 11 illustrates that the matching degree between the feature extracted from the sensor time-series data of the sensor ID: S001 and the collation data corresponding to the feature extracted from the sensor time-series data detected by the “Zone Temperature Sensor” is 0.5.

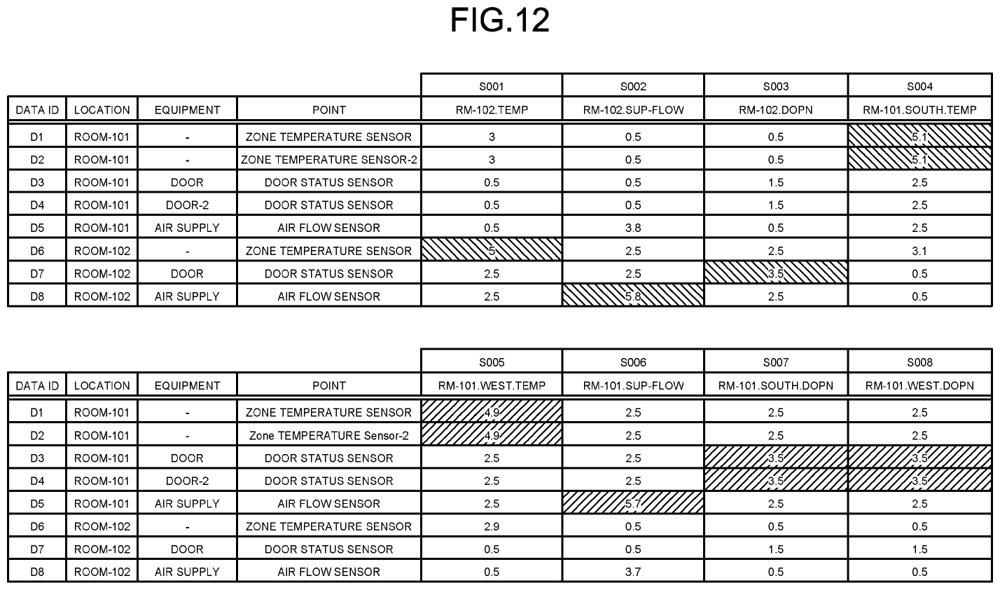

In the case of calculating both the matching degree of the character string and the matching degree of waveforms, the estimation module 112 further calculates a value obtained by adding the both. FIG. 12 is a diagram illustrating an example of the added matching degree. FIG. 12 corresponds to a diagram obtained by adding the matching degree of waveforms illustrated in FIG. 11 to the matching degree of the character string illustrated in FIG. 10.

In the example of FIG. 12, since there are other data IDs having the same value of the matching degree for the data IDs: D1, D2, D3, and D4, the corresponding sensor IDs cannot be determined. On the other hand, since there is no other data ID having the same value of the matching degree for the data IDs: D5, D6, D7, and D8, one corresponding sensor ID for each data ID is determined.

It is assumed that mapping data as illustrated in FIG. 12 is obtained in the estimation process (step S105) performed by the estimation module 112 in the loop in FIG. 7 performed the first time.

In step S106, it is determined whether to end the mapping estimation process. In this example, since there are half of the data IDs for which the sensor ID is not determined, it is determined that the process is not ended.

In step S107, a process corresponding to preparation of the next loop is performed. For example, a simulation scenario for simulation of the next loop (step S103) is determined. As described above, the process in accordance with designation by the user may be performed here.

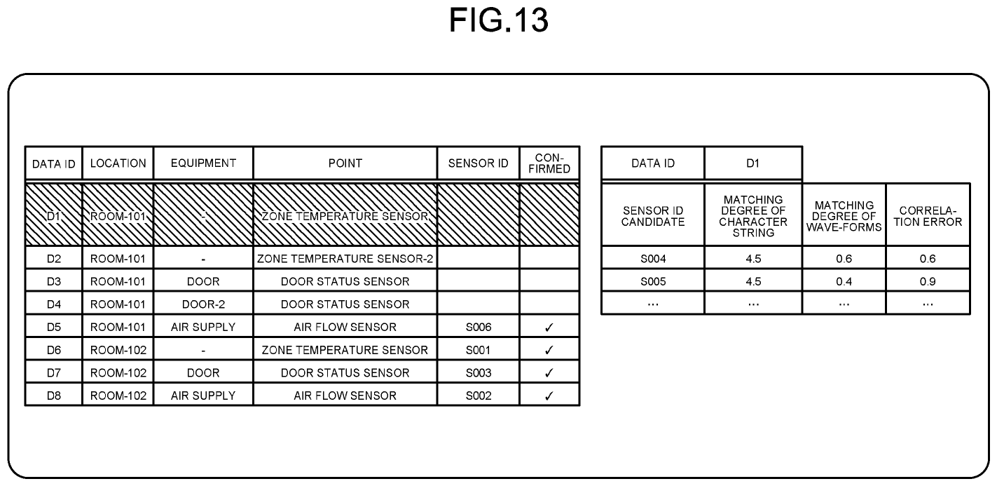

For example, the output control module 116 displays a confirmation screen for confirming the estimation result of the mapping data on the display unit 131. FIG. 13 is a diagram illustrating an example of the confirmation screen. As illustrated in FIG. 13, the confirmation screen includes the sensor IDs determined up to the point in time of the estimation result confirmation. The user can determine the corresponding sensor ID by designating a check in the “confirmed” column, for example.

The confirmation screen may be configured to display a plurality of sensor ID candidates and allow the user to select either one of the candidates. For example, when the user selects the data ID: D1, the output control module 116 displays the details of the estimated result for the data ID: D1. In the example of FIG. 13, two sensor ID candidates (S004 and S005) are displayed for the data ID: D1. The matching degree of the character string, the matching degree of waveforms and the correlation error are correspondingly displayed for each candidate as auxiliary information for assisting the selection of the user. The correlation error will be discussed below.

The confirmation screen may further include auxiliary information other than those described above. The auxiliary information includes, for example, sensor time-series data for each sensor ID and metadata associated with the sensor ID.

When correction of the mapping data is designated by the user, the mapping data is corrected according to the designation.

The designation by the user is not essential, and the simulation scenario may be determined according to the estimation result at the point in time of the estimation result confirmation. For example, the simulation module 114 obtains a data ID for which the corresponding sensor ID is not determined to one, and determines a simulation scenario according to the obtained data ID. In the example of FIG. 12, the sensor IDs are not determined for the data IDs: D1, D2, D3, and D4. Therefore, the simulation module 114 determines a simulation scenario so as to perform simulation only on the following simulation targets.
Location: “Room-101”
Types of sensors: all “Zone Temperature Sensor” and all “Door Status Sensor}

After the step described above, in step S103 of the loop performed the second time, the simulation according to the determined simulation scenario is performed. When the simulation is performed, correlation analysis between simulation data can be performed as preprocessing. Mapping data can be estimated from a correspondence between a correlation analysis result between simulation data and a correlation analysis result between sensor data. The estimation of the mapping data using the correlation analysis result will be described below.

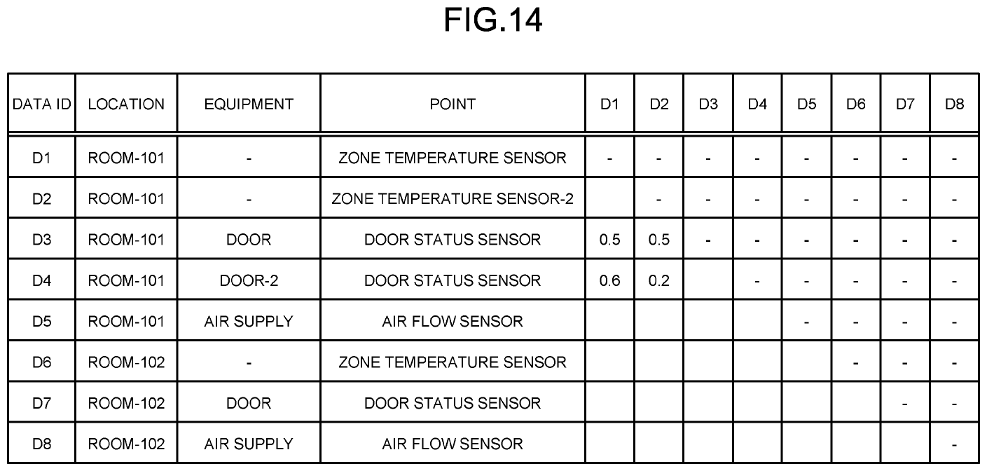

In step S104, the preprocessing module 111 performs, for example, time-series correlation analysis on the simulation data obtained in step S103. FIG. 14 is a diagram illustrating an example of correlation data that is a result of time-series correlation analysis on simulation data. The correlation data for the simulation data has the same format as that of FIG. 8 that illustrates the correlation data for the sensor data.

If simulation is performed only for data IDs of which each is not determined to have one sensor ID, correlation analysis is performed only for between simulation data corresponding to these data IDs. In the above example, the preprocessing module 111 performs correlation analysis between simulation data corresponding to the data IDs: D1, D2, D3, and D4.

In the example of FIG. 12, it is not determined which of the sensor IDs: S004 and S005 each of the data IDs: D1 and D2 corresponds to. It is not determined which of the sensor IDs: S007 and S008 each of the data IDs: D3 and D4 corresponds to. Therefore, there are the following four combinations indicating the corresponding candidates of the data IDs: D1, D2, D3, and D4 and the sensor IDs: S004, S005, S007, and S008.
(D1, D2, D3, D4)=(S004, S005, S007, S008)
(D1, D2, D3, D4)=(S005, S004, S007, S008)
(D1, D2, D3, D4)=(S004, S005, S008, S007)
(D1, D2, D3, D4)=(S005, S004, S008, S007)

For each of the four combinations, the estimation module 112 calculates a correlation error representing an error between a correlation analysis result (first correlation data) between simulation data and a correlation analysis result (second correlation data) between sensor data. The estimation module 112 estimates mapping data based on the calculated correlation error. For example, the estimation module 112 obtains a combination having a smaller correlation error than other combinations (e.g., a combination having the smallest correlation error). Thus, the sensor IDs corresponding to all the data IDs can be determined.

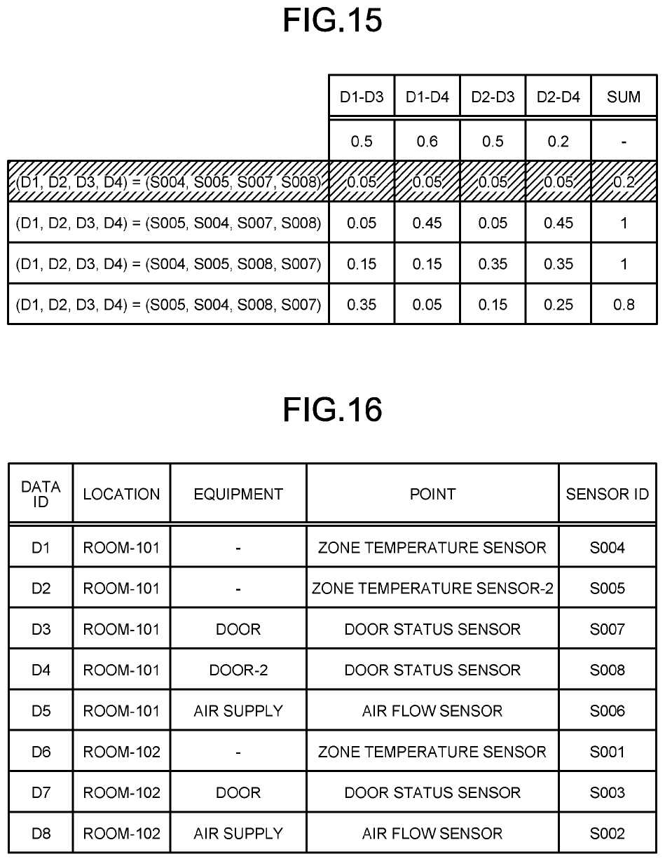

FIG. 15 is a diagram illustrating an example of calculation of a correlation error for each combination. For example, “D1-D3” and the corresponding numerical value “0.5” indicate a value representing the correlation between the simulation data corresponding to the data ID: D1 and the simulation data corresponding to the data ID: D3. The same applies to “D1-D4”, “D2-D3”, and “D2-D4”.

For example, in the case of the combination in the first row, the value representing the correlation between “D1-D3” is “0.5” (FIGS. 14 and 15). On the other hand, for this combination, the data IDs: D1 and D3 correspond to the sensor IDs: S004 and S007, respectively. The correlation between the sensor data corresponding to the sensor IDs: S004 and S007 is “0.45” as illustrated in FIG. 8. Therefore, the correlation error for “D1-D3” is 10.5-0.451=0.05.

The estimation module 112 similarly calculates correlation errors for “D1-D4”, “D2-D3”, and “D2-D4”, and calculates a total value (SUM) of the calculated correlation errors. In the example of FIG. 15, the total value is 0.2. The estimation module 112 similarly calculates the total value of the correlation errors for the other three combinations. The estimation module 112 then adopts the combination of the first row having the smallest total value of the correlation errors. In other words, the estimation module 112 estimates that the data IDs: D1, D2, D3, and D4 correspond to the sensor IDs: S004, S005, S007, and S008, respectively. FIG. 16 is a diagram illustrating an example of mapping data in which the sensor IDs are estimated for all the data IDs in this manner.

When calculating the total value of the correlation errors, the estimation module 112 may perform processing such as multiplying the correlation error between specific types of sensors by a parameter (weight) and then adding the correlation error.

The parameter can be interpreted as a parameter of a learning model for obtaining a correlation error. The learning module 113 may learn the parameters of the learning model using correct answer data.

In the subsequent step S106, since the number of data IDs of which each is not determined to have one corresponding sensor ID is 0, it is determined that the mapping estimation process is to be ended.

In this example, one sensor ID for each data ID can be determined to be a candidate for all the data IDs. On the other hand, there may be a case where one corresponding sensor ID for each data ID cannot be determined because there is no difference in the matching degree or the correlation error. In such a case, the process can be configured such that the user can select the corresponding sensor ID on the confirmation screen as illustrated in FIG. 13 described above.

Although the method using the correlation analysis result has been described as the estimation method of the mapping data using the simulation data, a method not using the correlation analysis result may be applied. For example, the estimation module 112 may estimate the mapping data from the matching degree between the waveform of the simulation data and the waveform of the sensor data.

Although an example in which the same number of data IDs and sensor IDs are associated with each other has been described above, the numbers of data IDs and sensor IDs do not need to be the same. For example, the same procedure as described above can be applied to a case of estimating which m (m is an integer greater than n) sensor IDs each of n (n is an integer greater than or equal to 1) data IDs corresponds to.

The information designated by the user in FIG. 13 or other figures can be used for learning of the learning model as correct answer data. The learning module 113 realizes learning of such a learning model. For example, the information designated by the user using the confirmation screen as illustrated in FIG. 13 is stored in the correct answer data storage unit 128 as correct answer data. The learning module 113 uses the stored correct answer data to learn the learning model stored in the learning model storage unit 127. The learning may be performed at any timing. For example, the learning is performed when a certain number or more of new correct answer data are stored and when the learning is designated by the user or other persons.

Such a configuration allows the learning model to be updated such that estimation can be performed with higher accuracy with respect to the currently analyzed equipment, for example.

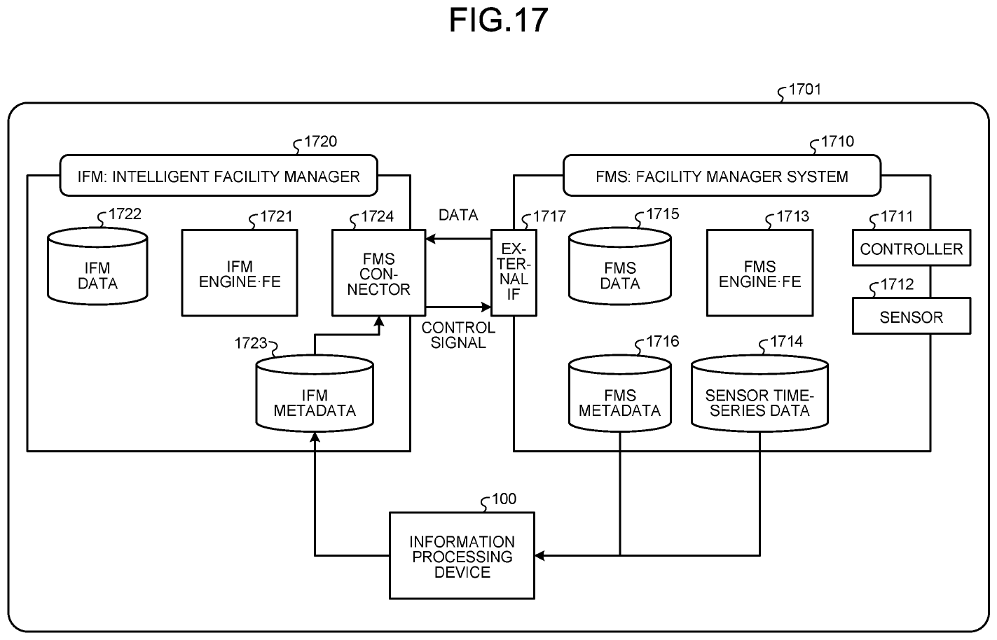

An example of an information processing system to which the information processing device 100 is applied will then be described. FIG. 17 is a diagram illustrating a configuration example of an information processing system 1701. The information processing system 1701 includes an FMS 1710, an IFM 1720, and the information processing device 100. The information processing system 1701 is, for example, a system in which the IFM 1720 is added to the existing FMS 1710 in order to implement a more advanced AI application.

The FMS 1710 includes a controller 1711, a sensor 1712, an FMS engine⋅FE 1713, sensor time-series data 1714, FMS data 1715, FMS metadata 1716, and an external interface (IF) 1717.

The controller 1711 controls various devices not illustrated. The sensor 1712 is a sensor for detecting sensor time-series data indicating the state of the device. Although one controller 1711 and one sensor 1712 are illustrated in FIG. 17, a plurality of controllers and sensors may be provided.

The FMS engine⋅FE 1713 controls devices to be managed, and displays a screen for management.

The sensor time-series data 1714 is sensor time-series data detected by the sensor 1712. The FMS metadata 1716 is metadata of, for example, the sensor 1712. The FMS data 1715 is used for controlling devices by the FMS engine⋅FE 1713, for example. These pieces of data are stored in a storage unit implemented by, for example, a flash memory.

The external IF 1717 is an interface for connecting to an external device such as the IFM 1720.

The IFM 1720 includes an IFM engine⋅FE 1721, IFM data 1722, IFM metadata 1723, and an FMS connector 1724.

The IFM engine⋅FE 1721 controls devices in the IFM 1720 and displays a screen for management. The IFM data 1722 is used for controlling devices by the IFM engine⋅FE 1721, for example. The FMS connector 1724 is a connector for connecting to the FMS 1710.

The IFM metadata 1723 is metadata used in the IFM 1720 and may be represented in a format different from the FMS metadata 1716 used in the FMS 1710. The information processing device 100 is used to estimate mapping data in which the IFM metadata 1723 and the FMS metadata 1716 are associated with each other.

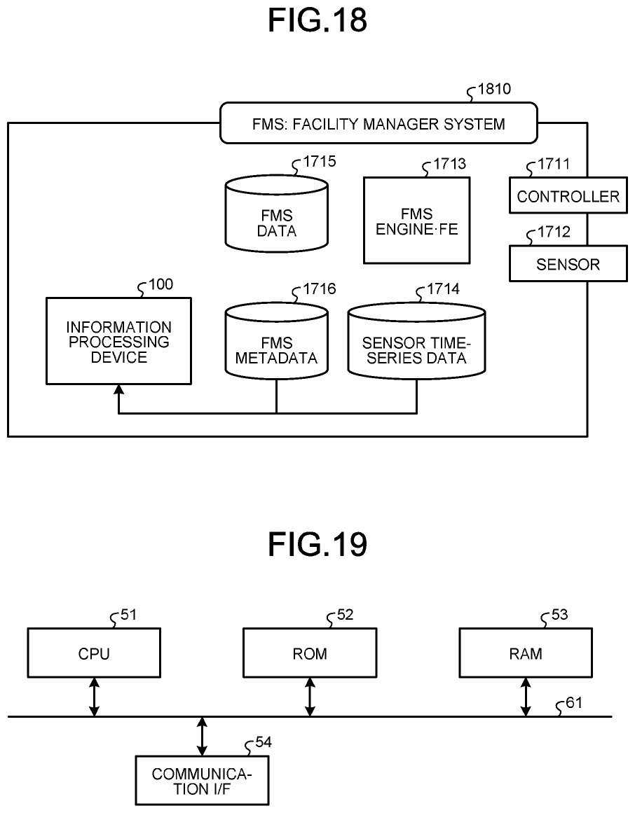

FIG. 18 is a diagram illustrating a configuration example of an FMS 1810 that is an information processing system different from that of FIG. 17. The FMS 1810 corresponds to a system configured to include the information processing device 100 therein.

There is a case where metadata is deviated from actual metadata due to initial setting of metadata and metadata change processing associated with maintenance of equipment. For example, it may be the case that the metadata is set differently from the expected values, such as by incorrectly performing an initial setting or change, or by placing a sensor in an incorrect position.

The information processing device 100 can be used to check such an error. For example, the information processing device 100 estimates the mapping data by the above procedure. The information processing device 100 then compares the estimated mapping data with correct mapping data (e.g., mapping data before metadata change), and determines whether an error occurs.

A specific example of a system to which the present embodiment can be applied will then be described. The present embodiment can be applied to, for example, a management system for managing building equipment. In a building equipment management system, sensor data of, for example, lights, doors, air conditioners, and room temperature meters are accumulated in many cases. In such a management system, it is assumed that the following phenomena occur.
The room temperature changes when the door opens.
The room temperature changes when the opening degree of the valve of the air conditioner changes.
The light turns on when the door opens.

The present embodiment can also be applied to a management system in, for example, a power generation equipment and a manufacturing plant. In such a management system, it is assumed that the following phenomena occur.
After the amount of heat generated by the heat source changes, the sensor data from the temperature sensor at a position close to the heat source changes.
After the amount of heat generated by the heat source changes, the chemical reaction proceeds.

The present embodiment can prepare a plurality of simulation scenarios for simulating the phenomena as described above, and switch according to the situation of estimation of the mapping data. Thus, simulation data that can be compared with the sensor time-series data can be efficiently generated.

The present embodiment can, by using simulation data in this manner, estimate metadata (mapping data) with more detailed granularity, and estimate more accurate metadata in a shorter period of time. For example, even in a case where there is a plurality of sensors of the same type, the use of the simulation data allows to estimate with highly accuracy in consideration of the physical arrangement of the sensors, for example. Consequently, a more advanced equipment management application can be introduced to achieve efficient management of equipment, for example.

The hardware configuration of the information processing device according to the present embodiment will then be described with reference to FIG. 19. FIG. 19 is an explanatory diagram illustrating a hardware configuration example of the information processing device according to the present embodiment.

The information processing device according to the present embodiment includes a control device such as a CPU 51, a storage device such as a read only memory (ROM) 52 or a RAM 53, a communication I/F 54 that is connected to a network for communication, and a bus 61 for connecting each unit.

The program executed by the information processing device according to the present embodiment is provided by being incorporated in the ROM 52 or other devices in advance.

The program executed by the information processing device according to the present embodiment may be recorded in a computer-readable recording medium such as a compact disk read only memory (CD-ROM), a flexible disk (FD), a compact disk recordable (CD-R), and a digital versatile disk (DVD) as a file in an installable or executable format and provided as a computer program product.

Further, the program executed by the information processing device according to the present embodiment may be stored on a computer connected to a network such as the Internet and provided by being downloaded via the network. The program executed by the information processing device according to the present embodiment may be provided or distributed via a network such as the Internet.

The program executed by the information processing device according to the present embodiment can cause a computer to function as each unit of the above-described information processing device. The computer allows the CPU 51 to read the program from the computer-readable storage medium onto the main storage device and execute the program.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processing device comprising:
one or more processors configured to:
perform, by using a model for performing a simulation of operations of a plurality of electronic devices, the simulation, and output a plurality of pieces of first data representing outputs by the plurality of electronic devices; and
estimate, based on the first data and a plurality of pieces of second data representing outputs obtained by operating the plurality of electronic devices, mapping data representing a correspondence between the plurality of electronic devices that output the first data and the plurality of electronic devices that output the second data.

2. The device according to claim 1, wherein the one or more processors are configured to estimate the mapping data based on the first data to which first metadata is given and the second data to which second metadata is given.

3. The device according to claim 1, wherein
the one or more processors are further configured to:
extract first feature data representing features of the plurality of pieces of first data and second feature data representing features of the plurality of pieces of second data; and
estimate the mapping data based on the first feature data and the second feature data.

4. The device according to claim 3, wherein the one or more processors are configured to extract the second feature data by analyzing the second metadata given to the second data.

5. The device according to claim 1, wherein the one or more processors are configured to determine a condition of the simulation based on mapping data obtained in advance.

6. The device according to claim 1, wherein the one or more processors are configured to determine a condition of the simulation based on the second data obtained in advance.

7. The device according to claim 1, wherein
the one or more processors are configured to:
determine whether or not estimation of the mapping data is ended; and
when the estimation of the mapping data is not ended, determine a condition of the simulation and further perform the simulation according to the determined condition.

8. The device according to claim 1, wherein
the one or more processors are further configured to:
calculate, by using a learning model learned to output a matching degree between the second data and the first data, the matching degree, and estimate the mapping data by using the calculated matching degree;
output the estimated mapping data; and
learn the learning model by using correct answer data of the mapping data set by referring to the outputted mapping data.

9. The device according to claim 1, wherein the one or more processors are configured to calculate an error between first correlation data representing a correlation between the plurality of pieces of first data and second correlation data representing a correlation between the plurality of pieces of second data, and estimate the mapping data based on the calculated error.

10. The device according to claim 1, wherein the model is a physical model for performing the simulation.

11. The device according to claim 1, wherein the one or more processors are configured to perform the simulation and output the plurality of pieces of first data representing the outputs by the plurality of electronic devices.

12. An information processing method performed by an information processing device, the method comprising:
performing, by using a model for performing a simulation of operations of a plurality of electronic devices, the simulation, and outputting a plurality of pieces of first data representing outputs by the plurality of electronic devices; and
estimating, based on the first data and a plurality of pieces of second data representing outputs obtained by operating the plurality of electronic devices, mapping data representing a correspondence between the plurality of electronic devices that output the first data and the plurality of electronic devices that output the second data.

13. A computer program product comprising a non-transitory computer-readable medium including programmed instructions, the instructions causing a computer to execute:
performing, by using a model for performing a simulation of operations of a plurality of electronic devices, the simulation, and outputting a plurality of pieces of first data representing outputs by the plurality of electronic devices, and
estimating, based on the first data and a plurality of pieces of second data representing outputs obtained by operating the plurality of electronic devices, mapping data representing a correspondence between the plurality of electronic devices that output the first data and the plurality of electronic devices that output the second data.

14. An information processing system comprising:
a plurality of electronic devices; and
an information processing device,
the information processing device comprising:
one or more processors configured to:
perform, by using a model for performing a simulation of operations of the plurality of electronic devices, the simulation, and output a plurality of pieces of first data representing outputs by the plurality of electronic devices; and
estimate, based on the first data and a plurality of pieces of second data representing outputs obtained by operating the plurality of electronic devices, mapping data representing a correspondence between the plurality of electronic devices that output the first data and the plurality of electronic devices that output the second data.
